(19) United States
(12) Patent Application Publication
(10) Pub. No.: US 2007/0080722 A1
(43) Pub. Date: Apr. 12, 2007

(54) Buffer

(75) Inventors: Shin Ho Chu, Icheon-shi (KR); Sun Mo An, Icheon-shi (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyunggi-do (KR)

(21) Appl. No.: 11/275,459

(22) Filed: Jan. 6, 2006

(30) Foreign Application Priority Data
Oct. 6, 2005 (KR) 2005-94051

(51) Int. Cl. H03B 1/00

(52) U.S. Cl. 327/112

(57) ABSTRACT

A buffer is disclosed. The buffer may include a buffering circuit for buffering an input signal, a buffer control circuit for outputting a first control signal which enables the buffering circuit responsive to an enable signal, and a second control signal which is enabled after the lapse of a predetermined period from a point of enable timing of the first control signal, and a logic unit for performing a logic operation with respect to an output signal from the buffering circuit and the second control signal from the buffer control circuit.

### FIELD OF THE INVENTION

This patent relates to a buffer, and more particularly to a command buffer in which a clock enable signal is delayed by a predetermined period through a circuit including a delay and a logic unit and then inputted to an output stage of the command buffer, thereby making it possible to prevent occurrence of a glitch on an output waveform of the command buffer.

### DESCRIPTION OF THE RELATED ART

In general, a command buffer, a clock enable buffer, a clock buffer, etc. are used in a dynamic random access memory (DRAM). The command buffer is adapted to receive command signals external to a chip, such as a row address strobe signal rasb, a column address strobe signal cas, a write enable signal web and a chip select signal csb, and generate internal command signals. The clock enable buffer is adapted to receive a clock enable signal ckeb external to the chip and generate an internal clock enable signal. The clock buffer acts to receive a clock signal external to the chip and generate an internal clock signal.

Where these buffers are used in a mobile DRAM technology, only a desired one(s) thereof is(are) enabled, whereas the remaining one(s), not used in DRAM operation, is(are) disabled, so that current consumption can be reduced in the DRAM operation.

FIG. 1 is a circuit diagram showing the configuration of a conventional command buffer.

The command buffer is enabled or disabled according to whether a clock enable signal ckeb assumes a low or high level, and the operation thereof will hereinafter be described with reference to FIG. 1.

First, in the case where the clock enable signal ckeb assumes a high level, the voltage of a node A and the voltage of a node B become low in level by an inverter IV11, and a PMOS transistor P21 in a switching circuit 210 is turned on by the low-level voltage of the node A and an NMOS transistor N21 in the switching circuit 210 is turned off by the low-level voltage of the node A. As a result, a signal processing circuit 220 is shut down by the turned-off NMOS transistor N21 and the voltage of a node C assumes a Vdd level, high level, by the turned-on PMOS transistor P21. This means that, when the clock enable signal ckeb is high in level, a buffering circuit 200 is disabled and the voltage of the node C becomes high in level irrespective of the level of an external command signal inputted to the signal processing circuit 220. Consequently, because the voltage of the node B is low in level and the voltage of the node C is high in level, an output signal from a NAND gate ND31 assumes a high level.

Next, in the case where the clock enable signal ckeb assumes a low level, the voltage of the node A and the voltage of the node B become high in level by the inverter IV11, and the PMOS transistor P21 in the switching circuit 210 is turned off by the high-level voltage of the node A and the NMOS transistor N21 in the switching circuit 210 is turned on by the high-level voltage of the node A. Accordingly, the signal processing circuit 220 is operated by the turned-on NMOS transistor N21 and the voltage level of the node C is thus determined depending on the level of an inverted signal of the inputted external command signal. As a result, when the inputted external command signal is high in level, the voltage of the node C becomes low in level, thereby causing the output signal from the NAND gate ND31 to assume a high level. On the contrary, when the external command signal is low in level, the voltage of the node C becomes high in level, thereby causing the output signal from the NAND gate ND31 to assume a low level.

In this manner, in the command buffer, whether the signal processing circuit 220 is to be operated is determined depending on whether the clock enable signal ckeb is enabled or disabled, and an internal command signal, enabled or disabled, is outputted through the logic operation of the NAND gate ND31. However, whether the switching of the switching circuit 210 is to be performed is determined according to the voltage level of the node A, and the signal processing circuit 220 is operated depending on the switching of the switching circuit 210, resulting in a certain delay time being taken for the signal output through the node C. Because the voltage of the node C has the previous level for the delay time, the internal command signal, outputted from the NAND gate ND31, has an abnormal voltage waveform with an inverted portion.

This problem with the conventional command buffer will hereinafter be described in detail with reference to a timing diagram of FIG. 2. It is assumed here that the external command signal inputted to the signal processing circuit 220 assumes a high level and the clock enable signal ckeb is toggled.

As stated previously, when the clock enable signal ckeb is high in level, the voltages of the node A and node B become low in level, so the PMOS transistor P21 in the switching circuit 210 is turned on, thereby causing the voltage of the node C to go high in level. As a result, the internal command signal, outputted by the logic operation of the NAND gate ND31, assumes a high level.

When the clock enable signal ckeb makes a high to low level transition in this state, the voltages of the node A and node B become high in level, so the NMOS transistor N21 in the switching circuit 210 is turned on, thereby causing the signal processing circuit 220 to be operated. As a result, the voltage of the node C assumes a low level, which is the level of an inverted signal of the inputted external command signal.

However, for the high to low level transition of the voltage of the node C, the switching of the switching circuit 210 must be performed based on the voltage level of the node A and the signal processing circuit 220 must be operated based on the switching of the switching circuit 210 to invert and output the inputted external command signal, resulting in a certain delay time being required. That is, at the time that the clock enable signal ckeb makes the high to low level transition, the voltage of the node B goes high in level at once, but the voltage of the node C is maintained at the previous level, high level, for the delay time and then goes low in level.

Hence, in the case where the clock enable signal ckeb makes the high to low level transition, a glitch phenomenon in which the output signal from the command buffer, or the internal command signal from the NAND gate ND31, falls to a low level occurs due to the high level state of the node C for the delay time, although the output signal from the command buffer must be maintained at the high level.

### SUMMARY OF THE INVENTION

A command buffer includes a clock enable signal that is delayed by a predetermined period through a circuit including a delay and a logic unit and then inputted to an output stage of the command buffer, thus making it possible to prevent occurrence of a glitch on an output waveform of the command buffer.

A buffer may include a buffering circuit for buffering an input signal; a buffer control circuit for outputting a first control signal which enables the buffering circuit in response to an enable signal, and a second control signal which is enabled after the lapse of a predetermined period from enable timing of the first control signal; and a first logic unit for performing a logic operation with respect to an output signal from the buffering circuit and the second control signal from the buffer control circuit.

Preferably, the buffering circuit includes: a switching circuit for performing switching in response to the first control signal; and a signal processing circuit activated by the switching of the switching circuit for buffering and outputting the input signal.

The enable signal may be a clock enable signal.

Preferably, the buffer control circuit includes: a second logic unit for performing a logic operation with respect to the enable signal and a specific voltage to output the first control signal; a delay for delaying the enable signal by the predetermined period; and a third logic unit for performing a logic operation with respect to the enable signal and an output signal from the delay to output the second control signal.

The specific voltage may be a ground voltage.

The second logic unit may perform a NOR operation with respect to the enable signal and the specific voltage.

The third logic unit may perform a NOR operation with respect to the enable signal and the output signal from the delay.

Alternatively, the buffer control circuit may include: an inverter for buffering the enable signal to output the first control signal; a delay for delaying the enable signal by the predetermined period; and a second logic unit for performing a logic operation with respect to the enable signal and an output signal from the delay to output the second control signal. Here, the second logic unit may perform a NOR operation with respect to the enable signal and the output signal from the delay.

The delay may delay the enable signal such that the second control signal makes a level transition at the same time that the output signal from the buffering circuit makes a level transition based on the enabled state of the enable signal.

### BRIEF DESCRIPTION OF THE DRAWINGS

Features and advantages of the present invention will be more clearly understood from the following detailed description taken in conjunction with the accompanying drawings, in which:

FIG. 1 is a circuit diagram showing the configuration of a conventional command buffer;

FIG. 2 is a timing diagram illustrating a glitch occurring in operation of the conventional command buffer;

FIG. 3 is a circuit diagram showing the configuration of a command buffer according to an exemplary embodiment of the present invention; and

FIG. 4 is a timing diagram illustrating an output waveform of the command buffer according to the embodiment of the present invention.

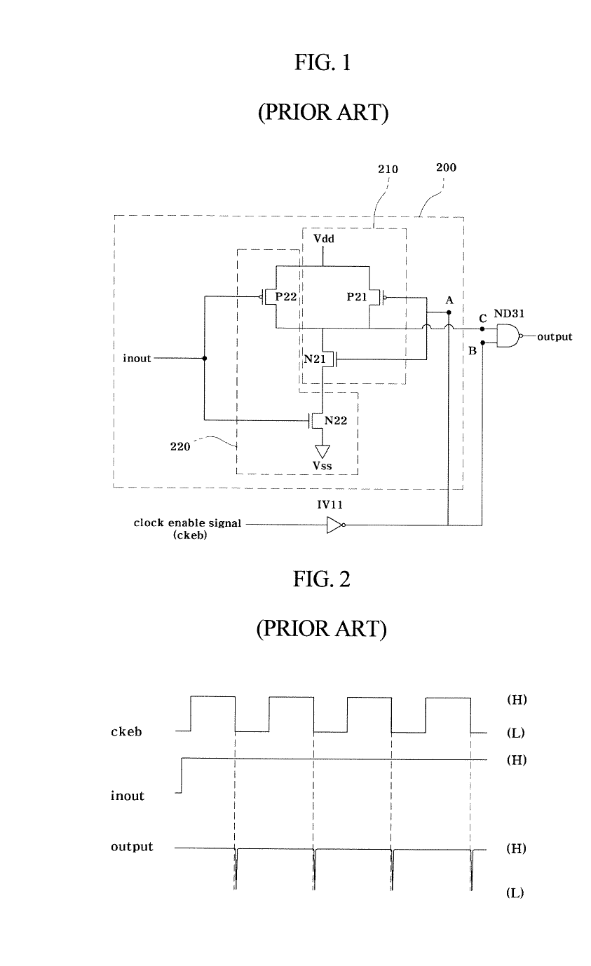

### DESCRIPTION OF THE PREFERRED EMBODIMENTS

Reference will now be made in detail to the preferred embodiments of the present invention, examples of which are illustrated in the accompanying drawings, wherein like reference numerals refer to like elements throughout. The embodiments are described below to explain the present invention by referring to the figures.

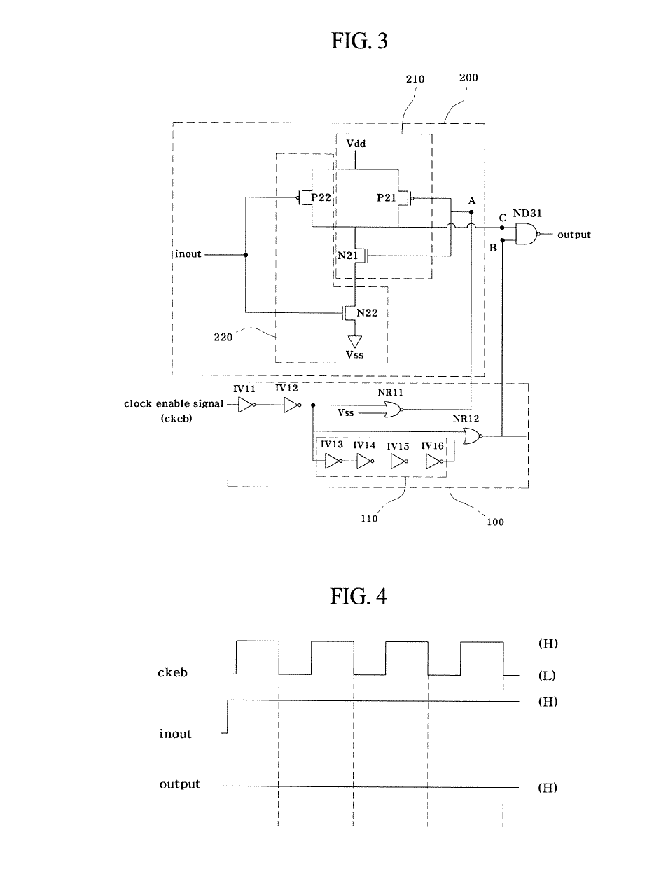

FIG. 3 is a circuit diagram showing the configuration of a command buffer according to an exemplary embodiment of the present invention, and FIG. 4 is a timing diagram illustrating an output waveform of the command buffer according to the embodiment of the present invention.

As shown in FIG. 3, the command buffer according to this embodiment comprises a buffering circuit 200 for buffering an input signal, a buffer control circuit 100 for outputting a first control signal which enables the buffering circuit 200 in response to an enable signal, and a second control signal which is enabled after the lapse of a predetermined period from enable timing of the first control signal, and a NAND gate ND31 for performing a logic operation with respect to an output signal from the buffering circuit 200 and the second control signal from the buffer control circuit 100.

The buffering circuit 200 includes a switching circuit 210 for performing switching in response to the first control signal, and a signal processing circuit 220 which is activated by the switching of the switching circuit 210 to buffer and output the input signal, or external command signal.

The buffer control circuit 100 includes a first logic unit NR11 for performing a logic operation with respect to the clock enable signal ckeb and a ground voltage Vss to output the first control signal, a delay 110 for delaying the clock enable signal ckeb by the predetermined period, and a second logic unit NR12 for performing a logic operation with respect to the clock enable signal ckeb and an output signal from the delay 110 to output the second control signal.

The first logic unit NR11 is a NOR gate for NORing the clock enable signal ckeb and the ground voltage Vss, and the second logic unit NR12 is a NOR gate for NORing the clock enable signal ckeb and the output signal from the delay 110.

On the other hand, the first logic unit NR11 may be composed of an inverter for inverting/buffering the clock enable signal ckeb. However, it should be noted here that the reason why the first logic unit NR11 is composed of a NOR gate in the present embodiment is to make the delay time of the first logic unit NR11 equal to that of the second logic unit NR12 composed of the same type of gate, or a NOR gate, so as to simultaneously cut off generation of an input signal to the buffering circuit 200 based on the first logic unit NR11 and generation of an input signal to the output stage of the command buffer based on the second logic unit NR12 when the command buffer is turned off.

The delay 110 includes a plurality of inverters IV13, IV14, IV15 and IV16. The number of inverters constituting the delay 110 is determined in such a manner that the voltage of a node B can make a level transition simultaneously with the lapse of a delay period taken until the voltage of a node C makes a level transition based on a level transition of the clock enable signal ckeb. At this time, provided that the voltages of the node B and node C make the level transitions based on the level transition of the clock enable signal ckeb at the same time by the operation of the delay 110, a glitch on the output waveform of the command buffer will be prevented.

The operation of the command buffer with the above-stated configuration according to the present embodiment will hereinafter be described with reference to FIG. 3 and FIG. 4, which illustrates an output waveform of the command buffer according to the embodiment of the present invention. It is assumed here that the external command signal inputted to the signal processing circuit 220 assumes a high level and the clock enable signal ckeb is toggled.

First, when the clock enable signal ckeb is high in level, the first logic unit NR11 NORs the clock enable signal ckeb of the high level and the ground voltage Vss and outputs the resulting signal as the first control signal of a low level. The second logic unit NR12 receives the clock enable signal ckeb of the high level at its one input terminal, so it outputs the second control signal of a low level irrespective of the level of an input signal at its other input terminal. Then, the low-level first control signal from the first logic unit NR11 is inputted to the buffering circuit 200 to turn on a PMOS transistor P21 in the switching circuit 210 and turn off an NMOS transistor N21 in the switching circuit 210. As a result, the voltage of the node C assumes a Vdd level, high level, irrespective of the level of the external command signal inputted to the buffering circuit 200.

Next, when the clock enable signal ckeb makes a high to low level transition, the first logic unit NR11 NORs the clock enable signal ckeb of the low level and the ground voltage Vss and outputs the resulting signal as the first control signal of a high level. At this time, the first logic unit NR11 may be composed of an inverter for inverting/buffering the input signal, or clock enable signal ckeb. Also, the clock enable signal ckeb of the low level is inputted directly to one input terminal of the second logic unit NR12 and through the delay 110 to the other input terminal of the second logic unit NR12. As a result, the second logic unit NR12 outputs the second control signal of a low level until the delayed clock enable signal ckeb is inputted, and then the second control signal of a high level from after the delayed clock enable signal ckeb is inputted.

The NMOS transistor N21 in the switching circuit 210 is turned on by the high-level first control signal, thereby causing the signal processing circuit 220 to be operated. As a result, the voltage of the node C assumes a low level, which is the level of an inverted signal of the high-level external command signal inputted to the signal processing circuit 220. Of course, as stated previously, for the high to low level transition of the voltage of the node C, the switching of the switching circuit 210 must be performed based on the voltage level of a node A and the signal processing circuit 220 must be operated based on the switching of the switching circuit 210 to invert and output the inputted external command signal, resulting in a certain delay period being required. Thus, the voltage of the node C is maintained at the previous level, high level, for the delay period.

As described above, the command buffer according to the present embodiment has no difference from the conventional command buffer in that the level transition of the node C based on the level transition of the clock enable signal ckeb is made after the lapse of the certain delay period. However, because the voltage of the node B which is NORed with the voltage of the node C by the NAND gate ND31 also makes a level transition after the lapse of the delay period of the delay 110, a glitch on the output of the command buffer can be prevented by making the level transition times of the node B and node C equal through adjustment of the number of inverters of the delay 110.

This technical concept of preventing a glitch in the command buffer is applicable to any other types of buffers, as well as the command buffer.

As apparent from the above description, the present invention provides a command buffer in which a clock enable signal is delayed by a predetermined period through a circuit including a delay and a logic unit and then inputted to an output stage of the command buffer, thereby making it possible to prevent occurrence of a glitch on an output waveform of the command buffer and thus to stabilize the operation of the command buffer.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A buffer comprising:
a buffering circuit for buffering an input signal;
a buffer control circuit for outputting a first control signal which enables the buffering circuit in response to an enable signal, and a second control signal which is enabled after the lapse of a predetermined period from enable timing of the first control signal; and
a first logic unit for performing a logic operation with respect to an output signal from the buffering circuit and the second control signal from the buffer control circuit.

2. The buffer as set forth in claim 1, wherein the buffering circuit includes:
a switching circuit for performing switching in response to the first control signal; and
a signal processing circuit activated by the switching of the switching circuit for buffering and outputting the input signal.

3. The buffer as set forth in claim 1, wherein the enable signal is a clock enable signal.

4. The buffer as set forth in claim 1, wherein the buffer control circuit includes:
a second logic unit for performing a logic operation with respect to the enable signal and a specific voltage to output the first control signal;
a delay for delaying the enable signal by the predetermined period; and
a third logic unit for performing a logic operation with respect to the enable signal and an output signal from the delay to output the second control signal.

5. The buffer as set forth in claim 4, wherein the specific voltage is a ground voltage.

6. The buffer as set forth in claim 4, wherein the second logic unit performs a NOR operation with respect to the enable signal and the specific voltage.

7. The buffer as set forth in claim 1, wherein the buffer control circuit includes:
an inverter for buffering the enable signal to output the first control signal;
a delay for delaying the enable signal by the predetermined period; and
a second logic unit for performing a logic operation with respect to the enable signal and an output signal from the delay to output the second control signal.

8. The buffer as set forth in claim 4, wherein the third logic unit performs a NOR operation with respect to the enable signal and the output signal from the delay.

9. The buffer as set forth in claim 7, wherein the second logic unit performs a NOR operation with respect to the enable signal and the output signal from the delay.

10. The buffer as set forth in claim 4, wherein the delay delays the enable signal such that the second control signal makes a level transition at the same time that the output signal from the buffering circuit makes a level transition based on the enabled state of the enable signal.

11. The buffer as set forth in claim 7, wherein the delay delays the enable signal such that the second control signal makes a level transition at the same time that the output signal from the buffering circuit makes a level transition based on the enabled state of the enable signal.
